(19) United States
(12) Patent Application Publication
(10) Pub. No.: US 2014/0230896 A1
(43) Pub. Date: Aug. 21, 2014

(54) SOLAR CELL AND METHOD OF FABRICATING THE SAME

(71) Applicant: LG INNOTEK CO., LTD., Seoul (KR)

(72) Inventor: Chin Woo Lim, Seoul (KR)

(73) Assignee: LG INNOTEK CO., LTD., Seoul (KR)

(21) Appl. No.: 14/346,232

(22) PCT Filed: Sep. 19, 2012
(86) PCT No.: PCT/KR2012/007504

§ 371 Date: Mar. 20, 2014

(30) Foreign Application Priority Data
Sep. 20, 2011 (KR) 10-2011-0094910

(51) Int. Cl. H01L 31/0224; H01L 31/0232

(52) U.S. Cl. CPC H01L 31/022425; H01L 31/02327
USPC 136/256; 438/69

(57) ABSTRACT

Disclosed are a solar cell and a method of fabricating the same. The solar cell includes a back electrode layer, a light absorbing layer on the back electrode layer, a front electrode layer on the light absorbing layer, and a plurality of light path changing particles in the front electrode layer or between the light absorbing layer and the front electrode layer.

### TECHNICAL FIELD

The embodiment relates to a solar cell and a method of fabricating the same.

### BACKGROUND ART

A method of fabricating a solar cell for solar light power generation is as follows. First, after preparing a substrate, a back electrode layer is formed on the substrate and patterned by a laser, thereby forming a plurality of back electrodes.

Thereafter, a light absorbing layer, a buffer layer, and a high resistance buffer layer are sequentially formed on the back electrodes. Various schemes, such as a scheme of forming a Cu(In,Ga)Se2 (CIGS) based-light absorbing layer by simultaneously or separately evaporating copper (Cu), indium (In), gallium (Ga), and selenium (Se) and a scheme of performing a selenization process after a metallic precursor film has been formed, have been extensively used in order to form the light absorbing layer. The energy band gap of the light absorbing layer is in the range of about 1 eV to 1.8 eV.

Thereafter, a buffer layer including cadmium sulfide (CdS) is formed on the light absorbing layer through a sputtering process. The energy bandgap of the buffer layer may be in the range of about 2.2 eV to 2.4 eV. Thereafter, a high resistance buffer layer including zinc oxide (ZnO) is formed on the buffer layer through the sputtering process. The energy bandgap of the high resistance buffer layer is in the range of about 3.1 eV to about 3.3 eV.

Thereafter, a groove pattern may be formed in the light absorbing layer, the buffer layer, and the high resistance buffer layer.

Thereafter, a transparent conductive material is laminated on the high resistance buffer layer, and is filled in the groove pattern. Therefore, a transparent electrode layer is formed on the high resistance buffer layer, and connection wires are formed in the groove pattern. A material constituting the transparent electrode layer and the connection wireless may include aluminum doped zinc oxide (AZO). The energy bandgap of the transparent electrode layer may be in the range of about 3.1 eV to about 3.3 eV.

Then, the groove pattern is formed in the transparent electrode layer, so that a plurality of solar cells may be formed. The transparent electrodes and the high resistance buffers correspond to the cell. The transparent electrodes and the high resistance buffers may be provided in the form of a stripe or a matrix.

The transparent electrodes and the back electrodes are misaligned from each other, so that the transparent electrodes are electrically connected to the back electrodes through the connection wires. Accordingly, the solar cells may be electrically connected to each other in series.

As described above, in order to convert the solar light into electrical energy, various solar cell apparatuses have been fabricated and used. One of the solar cell apparatuses is disclosed in Korean Unexamined Patent Publication No. 10-2008-0088744.

### DISCLOSURE OF INVENTION

### Technical Problem

The embodiment provides a solar cell capable of improved photo-electric conversion efficiency and a method of fabricating the same.

### Solution to Problem

According to the embodiments, there is provided a solar cell including a back electrode layer, a light absorbing layer on the back electrode layer, a front electrode layer on the light absorbing layer, and a plurality of light path changing particles in the front electrode layer or between the light absorbing layer and the front electrode layer.

According to the embodiments, there is provided a method of fabricating a solar cell. The method includes forming a rear electrode layer on a substrate, forming a light absorbing layer on the rear electrode layer, forming a front electrode layer on the light absorbing layer, and forming a plurality of light path changing particles between the light absorbing layer and the front electrode layer or in the front electrode layer.

### ADVANTAGEOUS EFFECTS OF INVENTION

As described above, the solar cell according to the embodiment includes the light path changing particles provided in the front electrode layer or between the front electrode layer and the light absorbing layer.

The light patch changing particles can change the path of light incident onto the light absorbing layer. In particular, the light path changing particles can change the path of light, which is incident onto the light absorbing layer in a vertical direction, to the path of light traveling in a horizontal direction.

Therefore, the light can be incident onto the light absorbing layer while representing a longer optical path due to the light path changing particles. Therefore, the solar cell according to the embodiment can maximize the path of the light in the light absorbing layer and can represent improved photo-electric conversion efficiency.

### BRIEF DESCRIPTION OF DRAWINGS

FIG. 1 is a sectional view showing a solar cell according to a first embodiment;

FIGS. 2 to 5 are sectional views showing a method of fabricating a solar cell according to the first embodiment;

FIG. 6 is a sectional view showing a solar cell according to a second embodiment; and

FIGS. 7 to 9 are sectional views showing a method of fabricating a solar cell according to a second embodiment.

### MODE FOR THE INVENTION

In the description of the embodiments, it will be understood that, when a substrate, a layer, a film, or an electrode is referred to as being “on” or “under” another substrate, another layer, another film, or another electrode, it can be “directly” or “indirectly” on the other substrate, layer, film, or electrode, or one or more intervening layers may also be present. Such a position of the layer has been described with reference to the drawings. The size of each element does not utterly reflect an actual size.

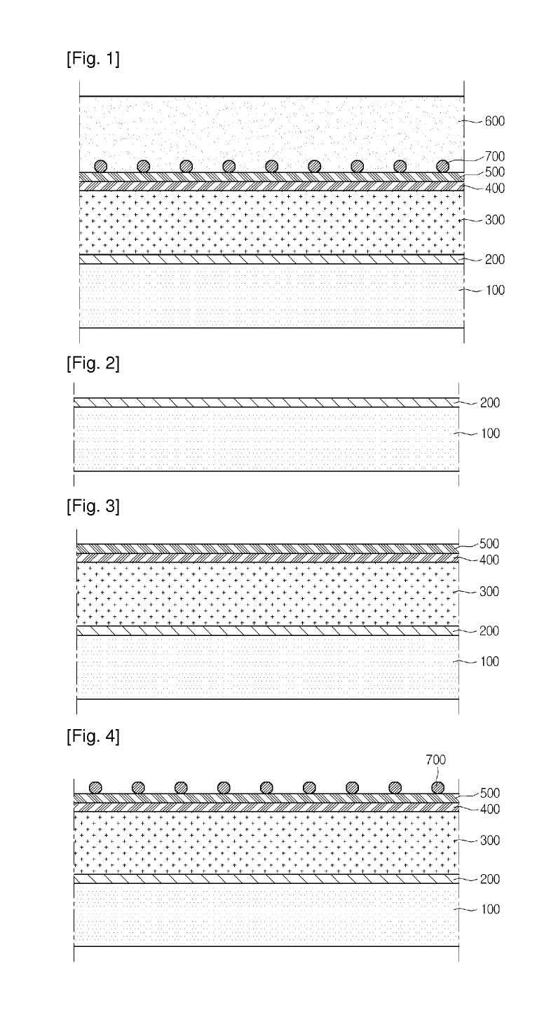

FIG. 1 is a sectional view showing a solar cell according to a first embodiment.

Referring to FIG. 1, the solar cell includes a support substrate 100, a back electrode layer 200, a light absorbing layer 300, a buffer layer 400, a high resistance buffer layer 500, a plurality of light path changing particles 700, and a front electrode layer 600.

The support substrate 100 has a plate shape and supports the back electrode layer 200, the light absorbing layer 300, the buffer layer 400, the high resistance buffer layer 500, and the front electrode layer 600.

The support substrate 100 may include an insulator. The support substrate 100 may include a glass substrate, a plastic substrate, or a metallic substrate. In more detail, the support substrate 100 may include a soda lime glass substrate. The support substrate 100 may be transparent or may be rigid or flexible.

The back electrode layer 200 is provided on the support substrate 100. The back electrode layer 200 may be a conductive layer. The back electrode layer 200 may include a metal, such as molybdenum (Mo).

In addition, the back electrode layer 200 may include at least two layers. In this case, the layers may be formed by using the homogeneous metal or heterogeneous metals.

The light absorbing layer 300 is provided on the back electrode layer 200. The light absorbing layer 300 includes a group I-III-VI compound. For example, the light absorbing layer 300 may have a Cu(In,Ga)Se2 (CIGS) crystal structure, a Cu(In)Se2 crystal structure, or a Cu(Ga)Se2 crystal structure.

The light absorbing layer 300 has an energy bandgap in the range of about 1 eV to about 1.8 eV.

The buffer layer 400 is provided on the light absorbing layer 300. The buffer layer 400 directly makes contact with the light absorbing layer 300. The buffer layer 400 includes CdS and has an energy bandgap in the range of about 1.9 eV to about 2.3 eV.

The high resistance buffer layer 500 is provided on the buffer layer 400. The high-resistance buffer layer 500 may include iZnO, which is zinc oxide not doped with impurities. The high resistance buffer layer 500 has an energy bandgap in the range of about 3.1 eV to about 3.3 eV.

The front electrode layer 600 is provided on the light absorbing layer 300. In more detail, the front electrode layer 600 is provided on the high resistance buffer layer 500.

The front electrode layer 600 is provided on the high resistance buffer layer 500. The front electrode layer 600 is transparent. The front electrode layer 600 may include a material such as Al doped ZnO (AZO), indium zinc oxide (IZO), or indium tin oxide (ITO).

The front electrode layer 600 may have a thickness of about 500 nm to about 1.5 μm. In addition, if the front electrode layer 600 includes AZO, aluminum (Al) may be doped with the content of about 2.5 wt % to about 3.5 wt %. The front electrode layer 600 is a conductive layer.

The light path changing particles 700 are provided between the light absorbing layer 300 and the front electrode layer 600. In more detail, the light path changing particles 700 may be provided between the buffer layer 400 and the front electrode layer 600. In more detail, the light path changing particles 700 may be provided between the high resistance buffer layer 500 and the front electrode layer 600.

In more detail, the light path changing particles 700 may be provided on the top surface of the high resistance buffer layer 500. In other words, the light path changing particles 700 may be directly provided on the interfacial surface between the front electrode layer 600 and the layer provided under the front electrode layer 600.

For example, if the buffer layer 400 and the high resistance buffer layer 500 are omitted, that is, if the front electrode layer 600 and the light absorbing layer 300 directly make contact with each other, the light path changing particles 700 may be directly provided on the interfacial surface between the light absorbing layer 300 and the front electrode layer 600. In addition, if the front electrode layer 600 directly makes contact with the buffer layer 400, the light path changing particles 700 may be directly provided on the interfacial surface between the buffer layer 400 and the front electrode layer 600.

In other words, the light path changing particles 700 may be provided on the same plane. In other words, the light path changing particles 700 may be spread on one plane. When viewed from the top, the light path changing particles 700 may cover about 5% to about 30% of the whole area of the top surface of the light absorbing layer 300.

The front electrode layer 600 may cover the light path changing particles 700. In other words, the front electrode layer 600 may be filled between the light path changing particles 700. The light path changing particles 700 may directly make contact with the front electrode layer 600.

The light path changing particles 700 may be conductive particles. In more detail, the light path changing particles 700 may be metallic particles. In more detail, the light path changing particles 700 may include gold, silver, or aluminum.

In addition, the diameters of the light path changing particles 700 may be in the range of about 1 nm to about 40 nm. In more detail, the diameters of the light path changing particles 700 may be in the range of about 1 nm to about 50 nm.

The light path changing particles 700 may change the path of the incident light. In detail, the light path changing particles 700 may scatter the incident light. In more detail, if the light path changing particles 700 may include metallic particles having a diameter of about 400 nm, the path of the incident light may be changed by a surface Plasmon effect. The path of the incident light may be easily changed due to the surface Plasmon effect on the interfacial surface between the light path changing particles 700 and the front electrode layer 600. In addition, the light path changing particles 700 may convert the wavelength of the incident light.

In addition, since the light path changing particles 700 are conductive particles, the electrical characteristic of the front electrode layer 600 can be improved. In particular, when the light path changing particles 700 are provided on the same plane, the loss of the transmittance in a vertical direction can be minimized, and the conductivity in a horizontal direction can be maximized.

Further, when the light path changing particles 700 include aluminum (Al), a portion of aluminum (Al) included in the light path changing particles 700 may be dispersed to the front electrode layer 600. Therefore, the aluminum concentration of the lower portion of the front electrode layer 600 may be relatively increased.

As described above, in the solar cell according to the present embodiment, the light path particles 700 are provided between the front electrode layer 600 and the light absorbing layer 300. The light path changing particles 700 may change the path of the light incident into the light absorbing layer 300. In particular, the light path changing particles 700 may change the path of the light, which is incident into the light absorbing layer 300 perpendicularly to the light absorbing layer 300, to a horizontal path.

Therefore, light may be incident onto the light absorbing layer 300 while representing a longer optical path due to the light path changing particles 700. Accordingly, in the solar cell according to the embodiment, the path of the light can be maximized in the light absorbing layer 300, and improved photo-electric conversion efficiency can be represented.

Therefore, the solar cell according to the present embodiment can represent improved optical characteristics and improved electrical characteristics by using the light path changing particles 700.

FIGS. 2 to 5 are sectional views showing a method of fabricating the solar cell according to the first embodiment. The method of fabricating the solar cell according to the present embodiment will be described by making reference to the above solar cell. The above description of the solar cell may be incorporated in the description of the method of fabricating the solar cell according to the present embodiment.

Referring to FIG. 2, metal such as molybdenum (Mo) is deposited on the support substrate 100 through the sputtering process, thereby forming the back electrode layer 200. The back electrode layer 200 may be formed through two processes having process conditions different from each other.

An additional layer such as an anti-reflective layer may be interposed between the support substrate 100 and the back electrode layer 200.

Referring to FIG. 3, the light absorbing layer 300 is formed on the back electrode layer 200.

The light absorbing layer 300 may be formed through a sputtering process or an evaporation scheme.

For example, the light absorbing layer 300 may be formed through various schemes such as a scheme of forming a Cu(In,Ga)Se2 (CIGS) based-light absorbing layer 300 by simultaneously or separately evaporating Cu, In, Ga, and Se and a scheme of performing a selenization process after a metallic precursor film has been formed.

Regarding the details of the selenization process after the formation of the metallic precursor layer, the metallic precursor layer is formed on the back contact electrode 200 through a sputtering process employing a Cu target, an In target, or a Ga target.

Thereafter, the metallic precursor layer is subject to the selenization process so that the Cu(In,Ga)Se2 (CIGS) based-light absorbing layer 300 is formed.

In addition, the sputtering process employing the Cu target, the In target, and the Ga target and the selenization process may be simultaneously performed.

In addition, a CIS or a CIG light absorbing layer 300 may be formed through a sputtering process employing only Cu and In targets or only Cu and Ga targets and the selenization process.

Thereafter, the buffer layer 400 and the high resistance buffer layer 500 are formed on the light absorbing layer 300.

The buffer layer 400 may be formed through a chemical bath deposition (CBD). For example, after the light absorbing layer 300 has been formed, the light absorbing layer 300 is immersed into a solution including materials used to form cadmium sulfide (CdS), and the buffer layer 400 including CdS is formed on the light absorbing layer 300.

Thereafter, zinc oxide is deposited on the buffer layer 400 through a sputtering process, thereby forming the high resistance buffer layer 500.

Referring to FIG. 4, a plurality of light path changing particles 700 are provided on the high resistance buffer layer 500. The light path changing particles 700 are directly provided on the high resistance buffer layer 500.

In addition, when the high resistance buffer layer 500 is omitted, the light path changing particles 700 may be directly provided on the buffer layer 400. In addition, when both of the buffer layer 400 and the high resistance buffer layer 500 are omitted, the light path changing particles 700 may be directly provided on the light absorbing layer 300.

The light path changing particles 700 may be provided on the high resistance buffer layer 500 through the following method.

First, the light path changing particles 700 are formed. The light path changing particles 700 may be formed in the form of nano-metallic particles through a sol-gel scheme, or a liquid phase synthesis scheme.

Subsequently, after the light path changing particles 700 are uniformly dispersed in the solvent, the light path changing particles 700 may be coated on the high resistance buffer layer 500.

Thereafter, the solvent is evaporated by heat, and only the light path changing particles 700 remain on the top surface of the high resistance buffer layer 500. After the solvent has been evaporated, the light path changing particles 700 are subject to heat treatment, so that the light path changing particles 700 may be fixed onto the top surface of the high resistance buffer layer 500. In this case, the light path changing particles 700 may be subject to the heat treatment at the temperature of about 150° C. to about 250° C.

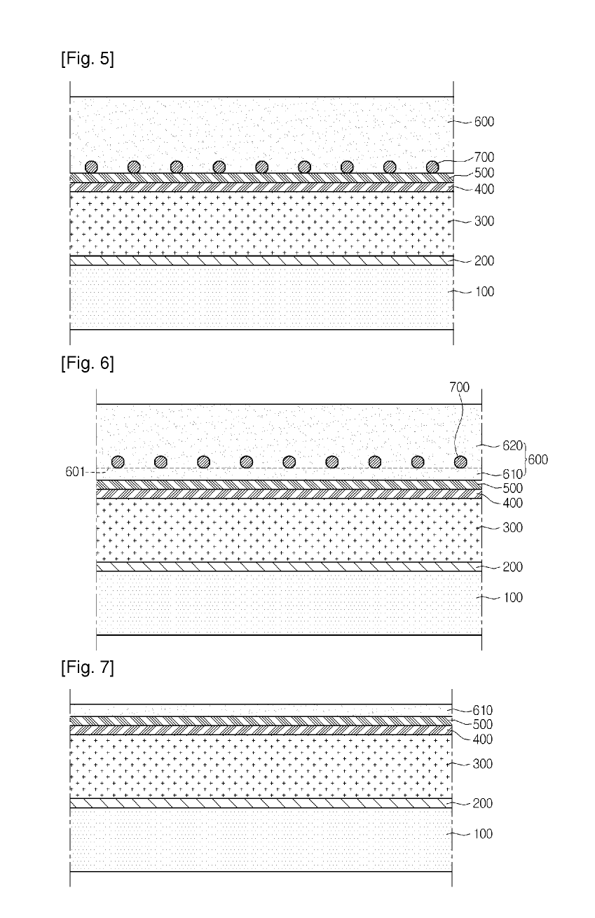

Referring to FIG. 5, the front electrode layer 600 is formed on the high resistance buffer layer 500. The front electrode layer 600 is formed by laminating transparent conductive materials, so that the front electrode layer 600 covers the light path changing particles 700 on the high resistance buffer layer 500. The transparent conductive material may include Al doped zinc oxide, indium zinc oxide, or indium tin oxide.

Therefore, the front electrode layer 600 is formed between the top surface of the high resistance buffer layer 500 and the light path changing particles 700.

Thereafter, the front electrode layer 600 and the light path changing particles 700 may be subject to heat treatment. For example, the front electrode layer 600 and the light path changing particles 700 may be subject to heat treatment at the temperature of 250° C.

As described above, the solar cell representing improved electrical and optical characteristics may be provided through a simple coating process of the light path changing particles 700.

FIG. 6 is a sectional view showing a solar cell according to the second embodiment. Hereinafter, the description of the present embodiment will be made by making reference to the description of the solar cell and the description of the method of fabricating the same, and the front electrode layer may be additionally described. The description of the above embodiments will be incorporated in the description of the present embodiment except for the modified part.

Referring to FIG. 6, the light path changing particles 700 are provided in the front electrode layer 600. In more detail, the front electrode layer 600 includes a first front electrode layer 610 provided on the light absorbing layer 300 and a second front electrode layer 620 provided on the first front electrode layer 610. In this case, the light path changing particles 700 are provided between the first and second front electrode layers 610 and 620.

The light path changing particles 700 directly make contact with an interfacial surface 601 between the first and second first electrode layers 610 and 620. In other words, the light path changing particles 700 may directly make contact with the top surface 601 of the first front electrode layer 610.

The first and second front electrode layers 610 and 620 may include the same material. Accordingly, the interfacial surface 601 may not be clearly provided between the first and second front electrodes layers 610 and 620. In this case, the light path changing particles 700 may be provided on the same virtual plane on the front electrode layer 600.

The thickness of the first front electrode layer 600 may vary depending on metals constituting the light path changing particles 700 or the diameter of the light path changing particles 700. For example, the thickness of the first front electrode layer 610 may occupy about 5% to about 95% of the thickness of the front electrode layer 600.

As described above, the light path changing particles 700 are provided in the front electrode layer 600, so that the optimal optical and electrical characteristics can be represented. In other words, the light path changing particles 700 are provided at a desirable height from the high resistance buffer layer 500, so that the path of the incident solar light can be changed in a desirable direction.

In addition, in the solar cell according to the present embodiment, the light path changing particles 700 are provided at a desirable height, and electrical conductivity can be maximized at a specific height. Therefore, in the solar cell according to the present embodiment, the electrical characteristic of the front electrode layer 600 can be maximized.

FIGS. 7 to 9 are sectional views showing the manufacturing process of a solar cell according to a second embodiment. Hereinafter, the method of fabricating the solar cell according to the present embodiment will be described by making reference to the above description of the above solar cell and the method of fabricating the same. The above description of the above solar cell and the method of fabricating the same will be incorporated in the description of the method of fabricating the solar cell according to the present embodiment.

Referring to FIG. 7, the back electrode layer 200, the light absorbing layer 300, the buffer layer 400, and the high resistance buffer layer 500 are provided on the support substrate 100. Thereafter, a transparent conductive material is deposited on the high resistance buffer layer 500, thereby forming the first front electrode layer 610. The first front electrode layer 600 may include Al doped zinc oxide, indium zinc oxide, or indium tin oxide.

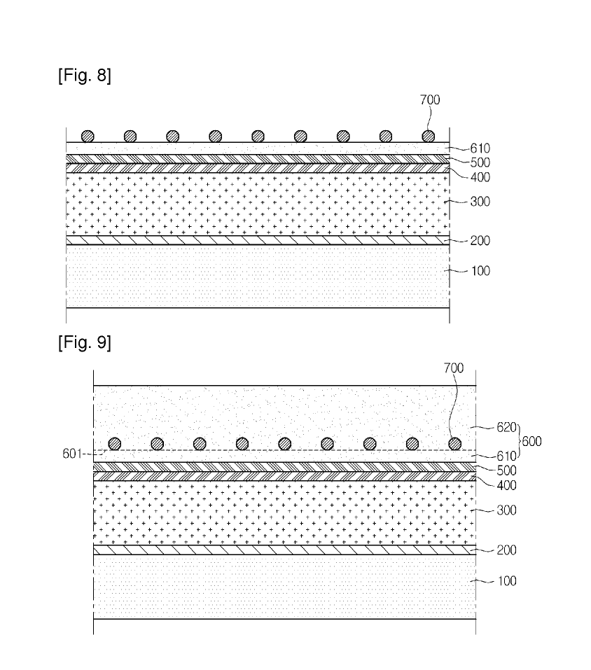

Referring to FIG. 8, the light path changing particles 700 are provided on the first front electrode layer 610. The light path changing particles 700 are uniformly dispersed into a solvent, so that the light path changing particles 700 are coated on the top surface of the first front electrode layer 610. Thereafter, the solvent is evaporated, and the light path changing particles 700 remain on the first front electrode layer 610.

Referring to FIG. 9, the second front electrode layer 620 is formed by depositing a conductive transparent material on the first front electrode layer 610. The second front electrode layer 620 may include the same material as that of the first front electrode layer 610. Accordingly, the interfacial surface between the first and second front electrode layers 610 and 620 are not clearly formed, but may be unclearly formed.

The thickness of the first front electrode layer 610 and the thickness of the second front electrode layer 620 are properly adjusted, so that the light path changing particles 700 may be provided at the optimal height.

Therefore, the solar cell fabricated according to the present embodiment can represent improved photo-electric conversion efficiency.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

1. A solar cell comprising:
a back electrode layer;
a light absorbing layer on the back electrode layer;
a front electrode layer on the light absorbing layer; and
a plurality of light path changing particles in the front electrode layer or between the light absorbing layer and the front electrode layer.

2. The solar cell of claim 1, wherein the light path changing particles serve as a conductor.

3. The solar cell of claim 2, wherein the light path changing particles include metal.

4. The solar cell of claim 3, wherein the light path changing particles include a material selected from the group consisting of gold (Au), silver (Ag), and aluminum (Al).

5. The solar cell of claim 1, wherein each light path changing particle has a diameter of about 1 nm to about 50 nm.

6. The solar cell of claim 1, wherein the light path changing particles scatter incident light.

7. The solar cell of claim 1, further comprising a buffer layer between the light absorbing layer and the front electrode layer, wherein the light path changing particles are directly provided on a top surface of the buffer layer.

8. The solar cell of claim 1, further comprising:
a buffer layer between the light absorbing layer and the front electrode layer; and
a high resistance buffer layer between the buffer layer and the front electrode layer,
wherein the light path changing particles are directly provided on an interfacial surface between the high resistance buffer layer and the front electrode layer.

9. The solar cell of claim 1, wherein the light path changing particles are provided on a same plane.

10. The solar cell of claim 1, wherein the front electrode layer comprises:
a first front electrode layer on the light absorbing layer; and
a second front electrode layer on the first front electrode, and
wherein the light path changing particles are interposed between the first and second front electrode layers.

11. The solar cell of claim 1, wherein the light path changing particles cover 5% to 30% of a whole area of a top surface of the light absorbing layer.

12. A method of fabricating a solar cell, the method comprising:
forming a rear electrode layer on a substrate;
forming a light absorbing layer on the rear electrode layer;
forming a front electrode layer on the light absorbing layer; and
forming a plurality of light path changing particles between the light absorbing layer and the front electrode layer or in the front electrode layer.

13. The method of claim 12, wherein, in the forming of the light path changing particles between the light absorbing layer and the front electrode layer or in the front electrode layer, the light path changing particles are provided on the light absorbing layer, and the front electrode layer covers the light path changing particles.

14. The method of claim 12, wherein, in the forming of the light path changing particles between the light absorbing layer and the front electrode layer or in the front electrode layer, the light path changing particles are dispersed in a solvent, and the solvent having the light path changing particles dispersed therein is coated on the light absorbing layer, and the solvent is removed.

15. The method of claim 12, wherein the forming of the front electrode layer on the light absorbing layer comprises:
forming a first front electrode layer on the light absorbing layer;
providing the light path changing particles on the first front electrode layer; and
forming a second front electrode layer on the light path changing particles.

16. The method of claim 15, wherein the first and second front electrode layers include a same material.

17. The method of claim 12, wherein the light path changing particles and the front electrode layer are subject to heat treatment.
